(19) United States
(12) Patent Application Publication
(10) Pub. No.: US 2026/0289053 A1
(43) Pub. Date: Sep. 24, 2026

(54) SHALE FRACTURE SEISMIC IDENTIFICATION METHOD BASED ON 3D U-NET CONVOLUTIONAL NEURAL NETWORK COMBINED WITH ANT TRACKING

(71) Applicants: China University of Petroleum (East China), Qingdao (CN); Yangtze University, Wuhan (CN)

(72) Inventors: Zhiyuan SUN, Qingdao (CN); Jiachang ZHANG, Qingdao (CN); Cunfei MA, Qingdao (CN); Tao LI, Wuhan (CN); Shouyu XU, Qingdao (CN)

(73) Assignees: China University of Petroleum (East China), Qingdao (CN); Yangtze University, Wuhan (CN)

(21) Appl. No.: 19/684,993

(22) Filed: May 21, 2026

Related U.S. Application Data
(63) Continuation of application No. PCT/CN2025/131920, filed on Oct. 31, 2025.

(30) Foreign Application Priority Data
Nov. 19, 2024 (CN) 2024116569266

(51) Int. Cl. G06F 30/27; G06N 3/0464

(52) U.S. Cl. CPC G06F 30/27; G06N 3/0464

(57) ABSTRACT

The invention relates to a shale fracture seismic identification method based on a 3D U-Net convolutional neural network combined with ant tracking. The method establishes a geological model of shale fractures using single-well data and performs seismic forward modeling to determine the advantageous frequency band for fracture identification. Spectral-peak decomposition is applied to obtain the advantageous frequency-band data volume, which is processed using a 3D U-Net convolutional neural network and ant-tracking computation to generate a 3D U-Net Ant Tracking volume. The results are verified using microseismic data, and along-layer attributes of the 3D U-Net Ant Tracking volume are extracted to determine the regional planar distribution characteristics of shale fractures. The method effectively reduces exploration costs by combining single-well and seismic data, significantly improves seismic resolution through integrated application of seismic forward modeling, spectral-peak decomposition, and advantageous frequency-band data computation.

### CROSS-REFERENCE TO RELATED APPLICATIONS

The application claims priority to Chinese patent application No. 2024116569266, filed on Nov. 19, 2024, the entire contents of which are incorporated herein by reference.

### TECHNICAL FIELD

The present invention relates to the field of seismic attribute identification for shale fractures, specifically to a shale fracture seismic identification method based on 3D U-Net convolutional neural network combined with ant tracking.

### BACKGROUND

Currently, the identification of shale fractures remains a key challenge in shale reservoir risk exploration, severely restricting the exploration and development of shale gas resources. Apart from core CT scanning, other methods such as single-attribute prediction, anisotropy, and fracture parameter inversion do not provide satisfactory prediction accuracy. CT scanning technology relies on drilling cores and can only identify fractures in small sections of core samples, offering limited insight into fractures throughout the entire shale region. In recent years, convolutional neural network (CNN) image processing techniques from the biomedical field have successfully been applied to small fault identification, but effective shale fracture identification has not yet been adequately studied. Ant tracking is highly sensitive to fracture differences in data volumes and is commonly combined with attributes such as coherence or curvature to identify fractures. While accurate identification of fractures with strong reflection characteristics in carbonate faults has been achieved, the identification of shale fractures, with less obvious fracture reflection characteristics, tends to result in excessive noise and interference, reducing identification accuracy. Therefore, developing a new method capable of efficiently and accurately identifying shale fractures is of great significance for advancing the deep exploration and development of shale gas resources.

The Longmaxi Formation shale layer, with a burial depth greater than 3500 meters, presents challenges due to low seismic data resolution and weak seismic responses from fractures. Conventional methods cannot identify small faults and fractures effectively. Additionally, the fracture prediction techniques in the Z215 well block area, such as seismic post-stack and pre-stack fracture prediction, are single and limited in accuracy, with no established verification standards. This has hindered the subsequent production operations in the Z215 well block area. In response, this invention proposes a method using a 3D U-Net convolutional neural network combined with ant tracking technology to improve shale fracture prediction accuracy, aiming to uncover shale fracture distribution patterns and provide robust support for safe production and efficient gas extraction in the Z215 well block area.

### SUMMARY

The objective of the present invention is to overcome the drawbacks of the existing technologies and provide a shale fracture seismic identification method based on a 3D U-Net convolutional neural network combined with ant tracking. This method considers the impact of seismic data resolution on fracture identification accuracy, first using seismic forward modeling to determine the optimal peak frequency band for shale fracture identification. Spectral peak decomposition is then performed to obtain seismic data with optimal resolution for shale fracture identification. Finally, a 3D U-Net convolutional neural network combined with ant tracking technology, along with microseismic monitoring, is used to verify and establish the seismic identification method for shale fractures. This method offers advantages such as low exploration costs, high identification accuracy, and wide identification range, effectively guiding shale layer well positioning and directly contributing to reducing shale gas extraction costs and improving production capacity.

### Technical Solution

The technical solution of the present invention is as follows:

The shale fracture seismic identification method based on a 3D U-Net convolutional neural network combined with ant tracking includes the following steps:
1. Preparation of primary data for shale fracture seismic prediction: Collecting well log data (including lithology, sonic time difference, and density), three-dimensional seismic data, and understanding the seismic data frequency spectrum peak characteristics and effective frequency band range;
2. Establishing a shale fracture geological model: Using well log data (lithology, sonic time difference, and density), establishing a shale fracture geological model for the Z215 well block, and performing seismic forward modeling on different peak frequency bands within the effective frequency band of seismic data to determine the optimal frequency band for shale fracture identification;
3. Performing spectral decomposition: Utilizing spectral decomposition technology on seismic data, adjusting the frequency band to match the optimal frequency band for shale

### Fracture Identification;

4. 3D U-Net convolutional neural network calculations: Performing 3D U-Net convolutional neural network calculations on the shale fracture identification advantage frequency band data volume to generate the 3D U-Net data;
5. Ant tracking calculations: Performing ant tracking calculations on the 3D U-Net data to generate the 3D U-Net Ant Tracking volume, and verifying the accuracy of shale fracture prediction using microseismic data;
6. Extracting layer properties: Extracting layer properties from the 3D U-Net Ant Tracking volume to derive regional shale fracture prediction results, providing intuitive fracture planar distribution results.

### Beneficial Effects of the Invention

The present invention has the following beneficial effects compared to existing technologies:
1. The method utilizes single-well data combined with seismic data to predict shale fractures, significantly reducing exploration costs;
2. The integrated method of seismic forward modeling-spectral peak decomposition-optimal frequency band data calculation maximizes the seismic resolution for shale fracture identification;
3. The combination of 3D U-Net convolutional neural network and ant tracking, along with microseismic data verification, greatly improves fracture identification accuracy;
4. Using data volumes to extract layer slices broadens the range of fracture identification.

### BRIEF DESCRIPTION OF THE DRAWINGS

FIG. 1 shows the analysis of the frequency-spectrum peaks and effective frequency band of the three-dimensional seismic data in the Z215 well block according to an embodiment of the present invention;

FIG. 2 shows the geological model of shale fractures established based on the well-logging data from the Z215 well block;

FIG. 3 shows the seismic forward-modeling results for different peak-frequency-band signals applied to the shale-fracture geological model based on the actual seismic dominant-frequency wavelet;

FIG. 4 shows a comparison between the seismic data at the advantageous frequency band for shale-fracture identification and the original seismic data in the Z215 well block;

FIG. 5 shows a schematic diagram of the processing workflow of the 3D U-Net data in the Z215 well block;

FIG. 6 shows the overlay of the 3D U-Net Ant Tracking volume profiles with microseismic data along wells H59 and H3 in the Z215 well block;

FIG. 7 shows the variance volume, 3D U-Net Ant Tracking volume, and their overlay with microseismic data along the layer near well H1 of the Longmaxi Formation in the Z215 well block.

### DETAILED DESCRIPTION OF THE EMBODIMENTS

To make the technical means adopted in the present invention and the objectives achieved more readily understood, the invention is further described below with reference to the accompanying drawings. Unless otherwise specified, the methods used in the following embodiments are conventional.

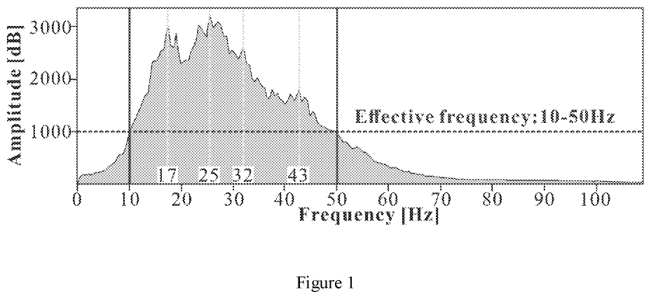

Referring to FIGS. 1-7, the invention is described in further detail as follows:

Step 1: Preparation of primary data for shale-fracture seismic prediction;

Taking the Z215 well block in the Zigong region of the southern Sichuan Basin as an example, three-dimensional seismic data, well-logging data (including lithology, sonic time difference, and density), and microseismic dynamic and static data are collected.

As shown in FIG. 1, the analysis of the seismic-body frequency spectrum indicates that when the seismic amplitude energy exceeds 0.3 (in the 10-50 Hz range), the seismic data fall within the effective frequency band. Within this band, multiple spectral peaks appear at 17 Hz, 25 Hz, 32 Hz, and 43 Hz.

Step 2: Establishment of the shale-fracture geological model;

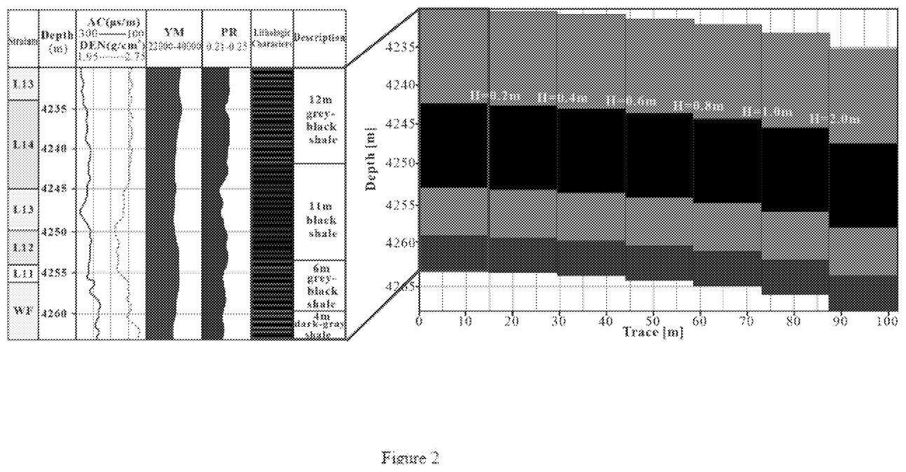

As shown in FIG. 2, a shale-fracture geological model for the Z215 well block is established using lithology, sonic time difference, and density well-log data. Fractures are modeled as small-displacement faults with displacements of 0.2 m, 0.4 m, 0.6 m, 0.8 m, 1.0 m, and 2.0 m.

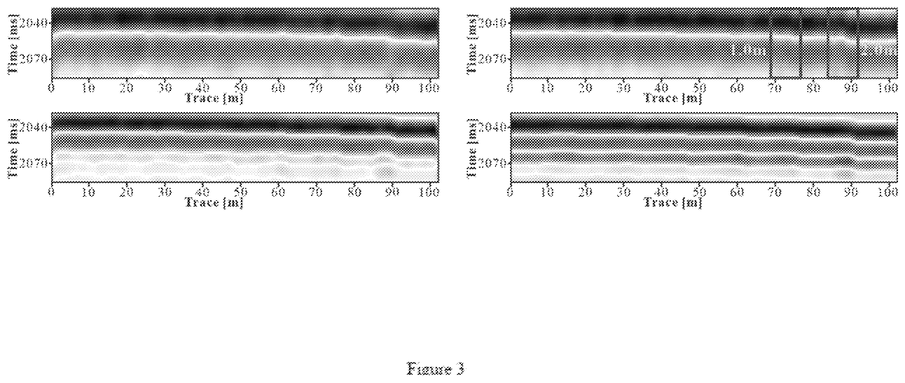

As shown in FIG. 3, seismic forward modeling is performed at different peak-frequency bands within the effective seismic frequency band. The results show that faults with displacements smaller than 2 m cannot be identified based solely on seismic reflection characteristics. However, when the dominant frequency is 25 Hz, the amplitude variations correspond well to fracture-development locations, indicating that 25 Hz is the advantageous frequency band for shale-fracture identification in the Z215 well block.

Step 3: Spectral-decomposition processing;

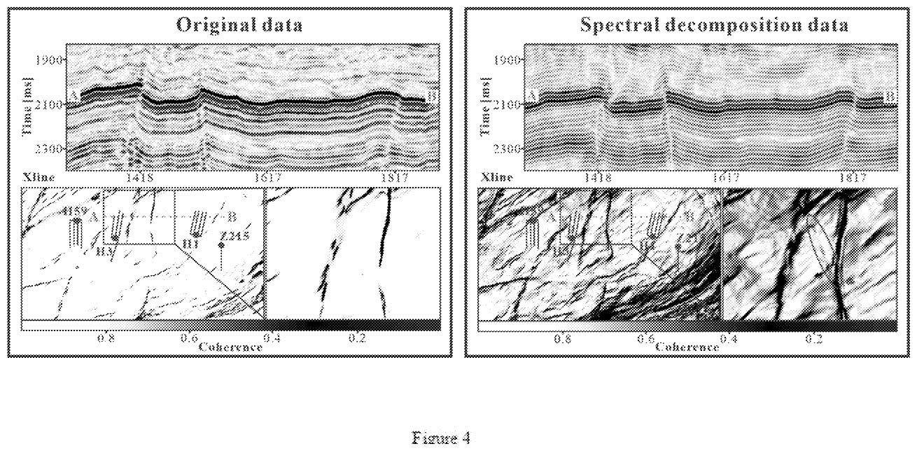

As shown in FIG. 4, based on the results of the seismic forward modeling and the frequency-spectrum characteristics of the three-dimensional seismic data, spectral decomposition is performed to obtain a 25 Hz advantageous frequency-band data volume for shale-fracture identification.

Compared with the original seismic data, the resolution of faults and fractures in the seismic profile is significantly enhanced. Extraction of the coherence attribute from the decomposed data enables the identification of northwest-oriented minor fractures.

Step 4: 3D U-Net convolutional-neural-network calculation;

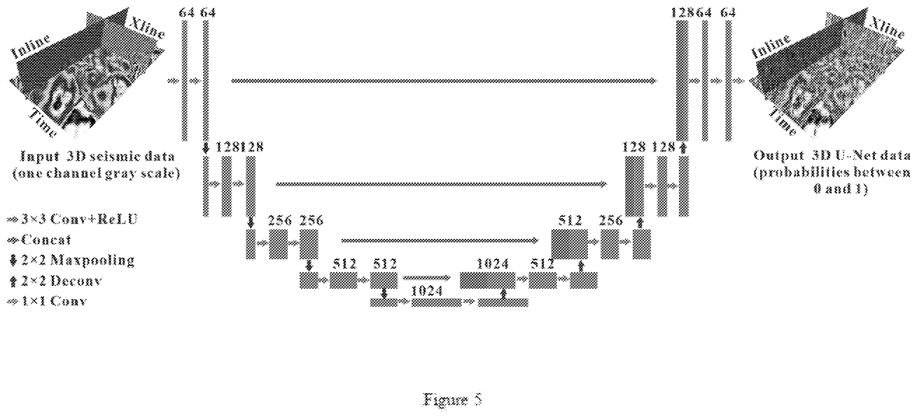

As shown in FIG. 5, the advantageous frequency-band data volume for shale-fracture identification is processed using the 3D U-Net convolutional neural network to generate the 3D U-Net data.

Step 5: Ant-tracking calculation and verification;

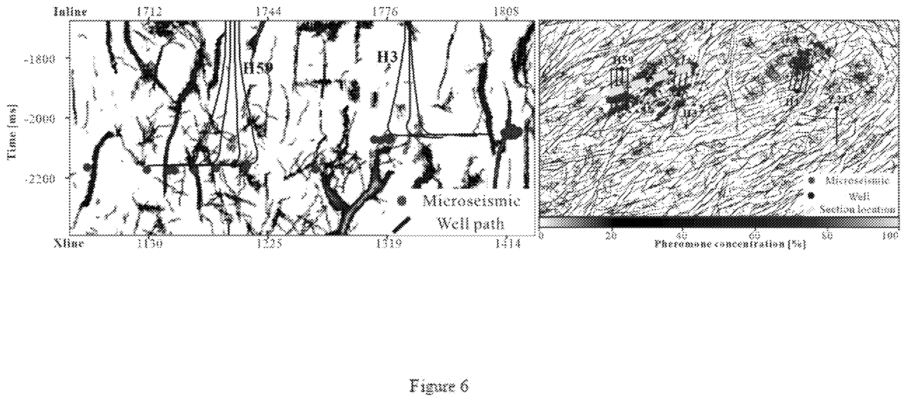

As shown in FIG. 6, the 3D U-Net data volume is subjected to ant-tracking calculations to obtain the 3D U-Net Ant Tracking volume. The accuracy of this volume is verified using microseismic data.

Step 6: Extraction of along-layer attributes and result analysis;

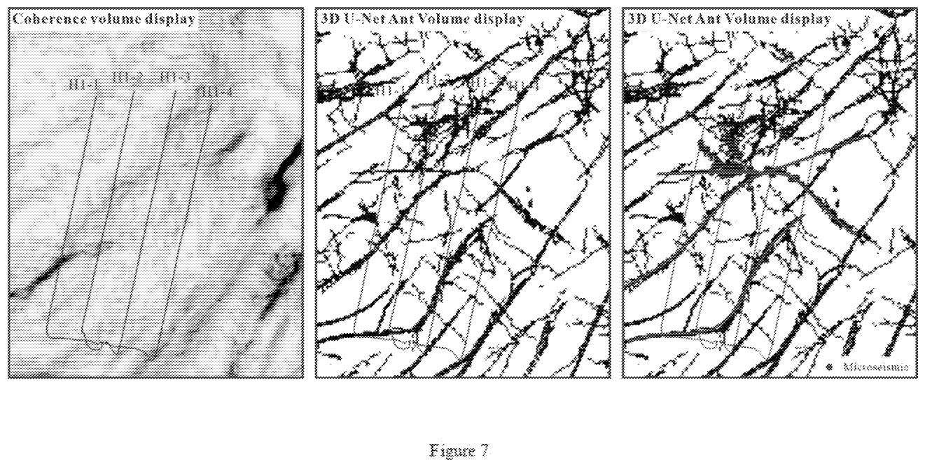

As shown in FIG. 7, the along-layer attributes are extracted from the 3D U-Net Ant Tracking volume to obtain regional shale-fracture prediction results.

Analysis of the results around the H1 horizontal well in the Z215 well block shows that conventional seismic attributes, such as the variance volume, perform poorly. In contrast, the 3D U-Net convolutional neural network combined with the ant-tracking algorithm successfully identifies northwest-trending fractures in the H1 platform, as well as two major northeast-trending faults, one near-east-west micro-fault, and a series of northwest-trending fractures across the entire H1 platform. The high consistency between the results and microseismic signals confirms the high accuracy of shale-fracture prediction.

The present invention has the following beneficial effects compared to existing technologies:
1. The method utilizes single-well data combined with seismic data to predict shale fractures, significantly reducing exploration costs;
2. The integrated method of seismic forward modeling-spectral peak decomposition-optimal frequency band data calculation maximizes the seismic resolution for shale fracture identification;
3. The combination of 3D U-Net convolutional neural network and ant tracking, along with microseismic data verification, greatly improves fracture identification accuracy;
4. Using data volumes to extract layer slices broadens the range of fracture identification.

What is claimed is:

1. A shale fracture seismic identification method based on a 3D U-Net convolutional neural network combined with ant tracking, characterized by: considering the impact of seismic data resolution on the accuracy of shale fracture identification, wherein a geological model for subsurface shale fractures is first established using well log data of lithology, sonic time difference, and density from a single well; seismic forward modeling is then used to determine the optimal peak frequency band for shale fracture identification; spectral peak decomposition is subsequently performed to obtain seismic data with optimal resolution for shale fracture identification; and finally, 3D U-Net convolutional neural network combined with ant tracking technology is used together with microseismic signal monitoring to verify and establish the seismic identification method for shale fractures, comprising the following steps:
(1) Preparation of primary data for shale fracture seismic prediction, wherein this invention uses the example of the Z215 well block in the southern Sichuan Basin Zigong area, collecting three-dimensional seismic data, lithology, sonic time difference, density well logging data, and microseismic signal data such as dynamic and static data from the Z215 well; understanding the seismic body frequency spectrum peak characteristics and effective frequency bands for the region;
(2) Establishing a shale fracture geological model for the Z215 well block based on lithology, sonic time difference, and density well log data, and performing seismic forward modeling on the different frequency bands within the effective frequency band of seismic data from step (1) to clarify the seismic response characteristics of shale fractures, and optimally selecting the best frequency band for seismic fracture identification;
(3) Performing spectral peak decomposition of seismic data based on the seismic forward modeling results of shale fracture response characteristics obtained in step (2) and the spectral characteristics of the three-dimensional seismic data in step (1), to obtain the shale fracture identification advantage frequency band data volume;
(4) Performing 3D U-Net convolutional neural network calculations on the shale fracture identification advantage frequency band data volume obtained in step (3) to generate the 3D U-Net data volume;
(5) Performing ant tracking calculations on the 3D U-Net data volume obtained in step (4) to generate the 3D U-Net Ant Tracking volume, and using microseismic signal data to verify the accuracy of the 3D U-Net Ant Tracking volume;
(6) Extracting the layer properties from the 3D U-Net Ant Tracking volume obtained in step (5) to derive regional shale fracture prediction results, providing intuitive fracture planar distribution results.

2. The method for seismic identification of shale fractures based on a 3D U-Net convolutional neural network combined with ant tracking according to claim 1, wherein the spectral peak decomposition refers to performing seismic forward modeling based on the seismic data frequency spectrum peak characteristics and effective frequency bands, optimizing the peak frequency band of seismic response for shale fractures, and utilizing spectral decomposition to decompose the peak frequency band to obtain the advantage data for shale fracture identification.

3. The method for seismic identification of shale fractures based on a 3D U-Net convolutional neural network combined with ant tracking according to claim 1, wherein the 3D U-Net convolutional neural network combined with ant tracking technology, involves using the 3D U-Net convolutional neural network to perform calculations on the advantage frequency band data volume for shale fracture identification to generate the 3D U-Net data volume, followed by ant tracking calculations to generate the 3D U-Net Ant Tracking volume.

4. The method for seismic identification of shale fractures based on 3D U-Net convolutional neural network combined with ant tracking as described in claim 1, wherein the verification of microseismic signal data involves overlaying the 3D U-Net Ant Tracking volume with microseismic data in both profile and plane views to validate the accuracy of the shale mud fracture prediction.
